(19) United States
(12) Patent Application Publication
(10) Pub. No.: US 2025/0210087 A1
(43) Pub. Date: Jun. 26, 2025

(54) MEMORY SYSTEM REFRESH

(71) Applicant: Micron Technology, Inc., Boise, ID (US)

(72) Inventor: Gianluca Coppola, Liveri (IT)

(21) Appl. No.: 18/975,658

(22) Filed: Dec. 10, 2024

Related U.S. Application Data
(60) Provisional application No. 63/613,947, filed on Dec. 22, 2023.

(51) Int. Cl. G11C 11/406

(52) U.S. Cl. CPC G11C 11/40607

(57) ABSTRACT

A method can be performed using a memory device. The method can include receiving a refresh command for first data or second data in the memory device. The method can include accessing a first of at least two registers in the memory device. The first register can be configured to store a first logical block address (LBA) at which the first data is stored in the memory device. A second of the at least two registers can be configured to store a range of LBAs at which at least the second data is stored in the memory device. The method can include performing a refresh operation to refresh one or both of the first data and the second data based on at least one of the first LBA and the range of LBAs.

### PRIORITY APPLICATION

This application claims the benefit of priority to U.S. Provisional Application Ser. No. 63/613,947, filed Dec. 22, 2023, which is incorporated herein by reference in its entirety.

### TECHNICAL FIELD

Embodiments of the disclosure relate generally to memory system refresh.

### BACKGROUND

A memory system can include one or more memory devices that store data. The memory devices can be, for example, non-volatile memory devices and volatile memory devices. In general, a host system can utilize a memory system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example of a computing system that includes a memory system in accordance with some embodiments of the present disclosure.

FIGS. 2A-2B illustrate examples of memory devices configured to refresh at least one LBA in accordance with some embodiments of the present disclosure.

FIG. 3 is an example of a flow diagram corresponding to a first method for refreshing at least one LBA in accordance with some embodiments of the present disclosure.

FIG. 4 is an example of a flow diagram corresponding to a second method for refreshing at least one LBA in accordance with some embodiments of the present disclosure.

FIG. 5 is an example of a flow diagram corresponding to a third method for refreshing at least one LBA in accordance with some embodiments of the present disclosure.

FIG. 6 is a block diagram of an example of a computer system in which embodiments of the present disclosure may operate.

### DETAILED DESCRIPTION

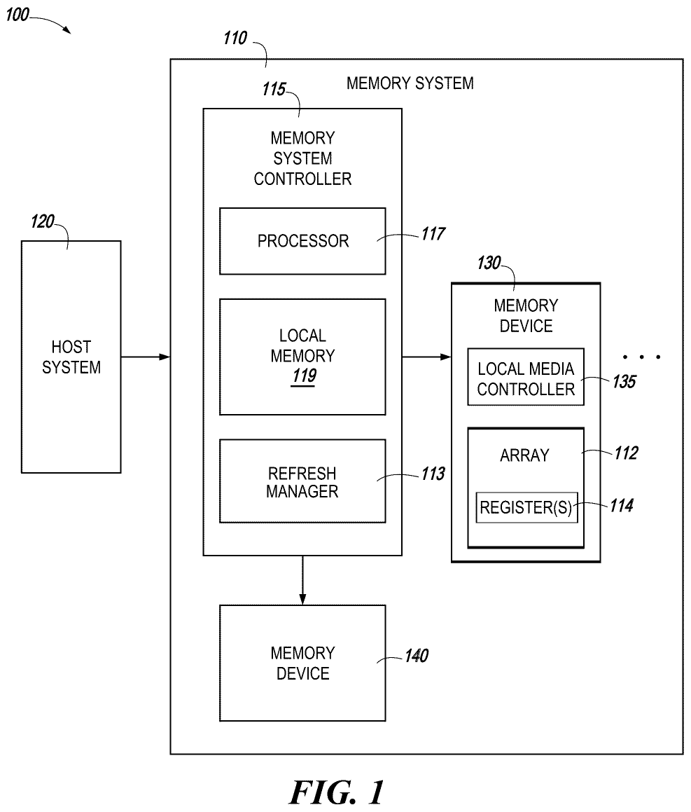

Aspects of the present disclosure are directed to a memory system for refreshing at least one logical block address (LBA), in particular to memory systems that include a refresh manager. A memory system can be a storage system, storage device, a memory module, or a combination of such. An example of a memory system is a storage system such as a solid-state drive (SSD). Examples of storage devices and memory modules are described below in conjunction with FIG. 1, et alibi. In general, a host system can utilize a memory system that includes one or more components, such as memory devices that store data. The host system can provide data to be stored at the memory system and can request data to be retrieved from the memory system.

A memory device can be a non-volatile memory device. One example of non-volatile memory devices is a not-and (NAND) memory device (also known as flash technology). Other examples of non-volatile memory devices are described below in conjunction with FIG. 1. A non-volatile memory device is a package of one or more dies or dice. Each die can consist of one or more planes. Planes can be grouped into logic units (LUN). For some types of non-volatile memory devices (e.g., NAND devices), each plane consists of a set of physical blocks. Each block consists of a set of pages. Each page consists of a set of memory cells (“cells”). A cell is an electronic circuit that stores information. A block hereinafter refers to a unit of the memory device used to store data and can include a group of memory cells, a word line group, a word line, or individual memory cells. For some memory devices, blocks (also hereinafter referred to as “memory blocks”) are the smallest area that can be erased. Pages cannot be erased individually, and only whole blocks can be erased.

Each of the memory devices can include one or more arrays of memory cells. Depending on the cell type, a cell can store one or more bits of binary information, and has various logic states that correlate to the number of bits being stored. The logic states can be represented by binary values, such as “0” and “1”, or combinations of such values. There are various types of cells, such as single level cells (SLCs), multi-level cells (MLCs), triple level cells (TLCs), and quad-level cells (QLCs). For example, a SLC can store one bit of information and has two logic states.

Some NAND memory devices employ a floating-gate architecture in which memory accesses are controlled based on a relative voltage change between the bit line and the word lines. Other examples of NAND memory devices can employ a replacement-gate architecture that can include the use of word line layouts that can allow for charges corresponding to data values to be trapped within memory cells based on properties of the materials used to construct the word lines.

During operation a memory system may perform a refresh operation on memory cells storing data. However, in some previous approaches, a refresh operation may not be able to select a particular LBA for refreshing. For example, a firmware initiated refresh operation can include refreshing a block of memory based on error correction code (ECC) counts, cell distribution, product status, etc. In some approaches, a refresh operation includes a manual force refresh (e.g., where a block of memory is refreshed regardless of block status) or a manual selective refresh (e.g., where a block of memory is refreshed only if indicated by a particular criteria, such as ECC count, cell distribution, etc., already described above). These approaches may not provide refresh capability at the logical block address level. In contrast, as will be described below, a host-initiated refresh operation can be provided at the LBA level.

Aspects of the present disclosure address the above and other deficiencies by providing registers in an array of memory cells of a memory device for storing logical block address information to perform the refresh operation at the LBA level. For example, in some embodiments, a first register can store a first LBA that stores a first set of data. A second register can store information about a range of LBAs, such as information about LBAs subsequent to the first LBA, on which to perform the refresh operation. One or more LBAs can be selected, using the information in the first or second registers, for performing the refresh operation. The approach described herein can reduce software overhead of the host and ensure specific LBAs are refreshed, for example, without refreshing an entire memory array or memory device of memory blocks. Further, the host may prefer to focus on particular LBAs for refresh as those particular LBAs may be more critical than other LBAs for application functionality (e.g., OS area). Refreshing more LBAs than is desired can have an impact on endurance and time for refreshing larger portions of LBAs.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

FIG. 1 illustrates an example computing system 100 that includes a memory system 110 in accordance with some embodiments of the present disclosure. The memory system 110 can include media, such as one or more volatile memory devices (e.g., memory device 140), one or more non-volatile memory devices (e.g., memory device 130), or a combination of such.

A memory system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, server, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory systems 110. In some embodiments, the host system 120 is coupled to different types of memory system 110. FIG. 1 illustrates one example of a host system 120 coupled to one memory system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system 120 uses the memory system 110, for example, to write data to the memory system 110 and read data from the memory system 110.

The host system 120 can be coupled to the memory system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory system 110. The host system 120 can further utilize an NVM Express (NVMe) interface to access components (e.g., memory devices 130) when the memory system 110 is coupled with the host system 120 by the PCle interface. The physical host interface can provide an interface for passing control, address, data, and other signals between the memory system 110 and the host system 120. FIG. 1 illustrates a memory system 110 as an example. In general, the host system 120 can access multiple memory systems via the same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random access memory (SDRAM).

Some examples of non-volatile memory devices (e.g., memory device 130) include flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130, 140 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLC) can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as three-dimensional cross-point arrays of non-volatile memory cells and NAND type memory (e.g., 2D NAND, 3D NAND) are described, the memory device 130 can be based on any other type of non-volatile memory or storage device, such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, and electrically crasable programmable read-only memory (EEPROM).

The memory system controller 115 (or controller 115 for simplicity) can communicate with the memory devices 130 to perform operations such as reading data, writing data, or crasing data at the memory devices 130 and other such operations. The memory system controller 115 can include hardware such as one or more integrated circuits and/or discrete components, a buffer memory, or a combination thereof. The hardware can include digital circuitry with dedicated (i.e., hard-coded) logic to perform the operations described herein. The memory system controller 115 can be a microcontroller, special purpose logic circuitry (e.g., a field programmable gate array (FPGA), an application specific integrated circuit (ASIC), etc.), or other suitable processor.

The memory system controller 115 can include a processor 117 (e.g., a processing device) configured to execute instructions stored in a local memory 119. In the illustrated example, the local memory 119 of the memory system controller 115 includes an embedded memory configured to store instructions for performing various processes, operations, logic flows, and routines that control operation of the memory system 110, including handling communications between the memory system 110 and the host system 120.

In some embodiments, the local memory 119 can include memory registers storing memory pointers, fetched data, etc. The local memory 119 can also include read-only memory (ROM) for storing micro-code. While the example memory system 110 in FIG. 1 has been illustrated as including the memory system controller 115, in another embodiment of the present disclosure, a memory system 110 does not include a memory system controller 115, and can instead rely upon external control (e.g., provided by an external host, or by a processor or controller separate from the memory system).

In general, the memory system controller 115 can receive commands or operations from the host system 120 and can convert the commands or operations into instructions or appropriate commands to achieve the desired access to the memory device 130 and/or the memory device 140. The memory system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address, physical media locations, etc.) that are associated with the memory devices 130. As an example, an LBA can refer to a linear addressing scheme that specifies the locations of data blocks in storage devices to find these data blocks or specified portions of data. The term can refer to both the address and the block to which it refers. The memory system controller 115 can further include host interface circuitry to communicate with the host system 120 via the physical host interface. The host interface circuitry can convert the commands received from the host system into command instructions to access the memory device 130 and/or the memory device 140 as well as convert responses associated with the memory device 130 and/or the memory device 140 into information for the host system 120.

The memory system 110 can also include additional circuitry or components that are not illustrated. In some embodiments, the memory system 110 can include a cache or buffer (e.g., DRAM) and address circuitry (e.g., a row decoder and a column decoder) that can receive an address from the memory system controller 115 and decode the address to access the memory device 130 and/or the memory device 140.

In some embodiments, the memory device 130 includes local media controllers 135 that operate in conjunction with memory system controller 115 to execute operations on one or more memory cells of the memory devices 130. An external controller (e.g., memory system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory system 110 can include a refresh manager 113. Although not shown in FIG. 1 so as to not obfuscate the drawings, the refresh manager 113 can include various circuitry to facilitate refresh and other related operations for a memory system and/or components of the memory system. In an example, the refresh manager 113 can be configured to determine when or whether to perform refresh operations for the memory system and/or components of the memory system based on, e.g., received commands from a host, data reliability parameters of the memory system and/or components of the memory system, or error correction parameters, among other things. In some embodiments, the refresh manager 113 can include special purpose circuitry in the form of an ASIC, FPGA, state machine, and/or other logic circuitry that can allow the refresh manager 113 to orchestrate and/or perform operations to selectively perform refresh operations for the memory device 130 and/or the memory device 140 based on host preferences and/or refresh parameters.

In some embodiments, the memory system controller 115 includes at least a portion of the refresh manager 113. For example, the memory system controller 115 can include a processor 117 (processing device) configured to execute instructions stored in local memory 119 for performing the operations described herein. In some embodiments, the refresh manager 113 is part of the host system 120, an application, or an operating system.

In a non-limiting example, an apparatus (e.g., the computing system 100) can include a memory system refresh manager 113. The memory system refresh manager 113 can be resident on the memory system 110. As used herein, the term “resident on” refers to something that is physically located on a particular component. For example, the memory system refresh manager 113 being “resident on” the memory system 110 refers to a condition in which the hardware circuitry that comprises the memory system refresh manager 113 is physically located on the memory system 110. The term “resident on” can be used interchangeably with other terms such as “deployed on” or “located on,” herein. The memory system refresh manager 113 can be configured to perform or cause to be performed, refresh operations on memory cells of an array of the memory device 130.

In some embodiments, the refresh manager 113 can cause the registers(s) 114 of the memory device 130 to be accessed in coordination with performance of a refresh operation. The register(s) (e.g., a first register) 114 can store a first logical block address (LBA) that indicates a location to start the refresh operation. The register(s) 114 (e.g., a second register) can store a range of LBAs subsequent to the first LBA to perform the refresh operation.

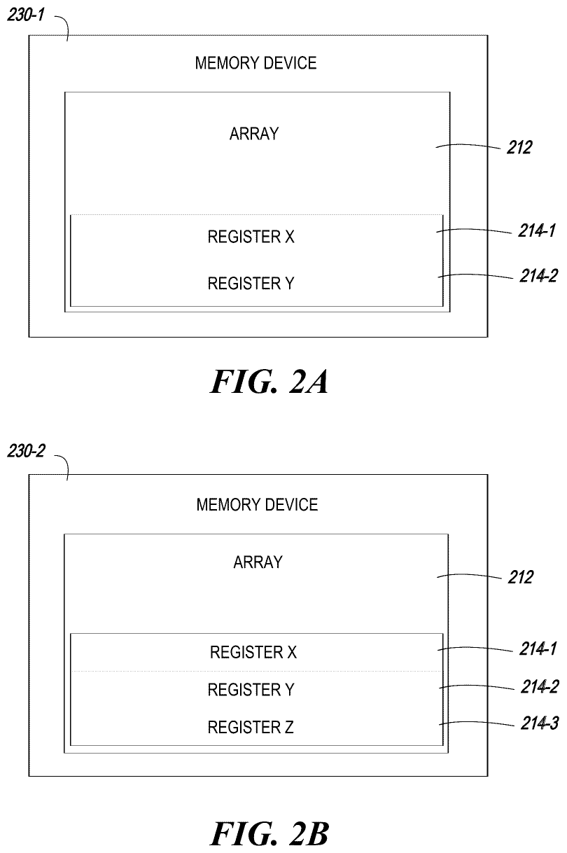

FIGS. 2A-2B illustrate examples of a memory device configured to refresh at least one LBA in accordance with some embodiments of the present disclosure. As illustrated in FIG. 2A, a memory device 230-1 can include an array 212 of memory cells. The array 212 of memory cells can include a first register (e.g., “register X”) 214-1 and a second register (e.g., “register Y”) 214-2. The first register 214-1 can have default values of “00h.” The first register 214-1 can be used to store a first LBA. The second register 214-2 can be used to store information about a range of LBAs and/or about the LBAs belonging to or within the range. The second register 214-2 can have default values of “00h.” In an example, the first register 214-1 can include information about where to start a refresh operation (e.g., at the first LBA) and the second register 214-2 can indicate an extent of the refresh operation, such as by including information about how many LBAs are to be refreshed by the refresh operation. In some examples, the range of LBAs can be used by performing a refresh operation on the first LBA and the range of LBAs minus 1. For example, if the range of LBAs is a value of ten (10), then the first LBA can be refreshed along with the next nine (9) LBAs.

The example of FIG. 2A can be used with a first approach for performing a refresh operation. The first approach can include a host (e.g., host system 120 in FIG. 1) sending a command to store a first LBA in the first register 214-1. The first approach can further include the host sending a command to store a range of LBAs in the second register 214-1. In some examples, a single command can be used to store the LBA and/or LBA range information in the first register 214-1 and the second register 214-2. In some examples, separate commands can be used to store data in the first register 214-1 and the second register 214-2 respectively. The host can later send a particular refresh command (e.g., “VU_A”) to the memory device 230-1 to perform the refresh operation. The particular refresh command can include an argument that includes a logical unit (LU) identification (ID). The LU ID can indicate which LU to use for locating the first LBA in the first register 214-1 and the range of LBAs in the second register 214-2.

In response to receiving the particular refresh command to perform the refresh operation from the host, the memory device 230-1 can access the second register 214-2 to determine whether the second register 214-2 stores a non-zero value. In response to the second register 214-2 storing a non-zero value, the memory device 230-1 can perform the refresh operation on the first LBA and the range of LBAs (such as subsequent to the first LBA) specified by the information from the second register 214-2. In response to the second register 214-2 storing a value of zero (“0”), the memory device 230-1 can either return an error message or perform other refresh operations based on other stored refresh data, such as ECC counts, cell distribution, product status, etc.

In the example of FIG. 2B, a memory device 230-2 can include an array 212 of memory cells. The array 212 of memory cells can include the first register (e.g., “register X”) 214-1, the second register (e.g., “register Y”) 214-2, and a third register (e.g., “register Z”) 214-3. The third register 214-3 can be used to indicate which logical unit (LU) includes the first LBA and the range of LBAs indicated by the first register 214-1 and the second register 214-2. In other words, the third register 214-3 can indicate the LU in which the first LBA and the range of LBAs are located, the first register 214-1 can indicate the first LBA, in the indicated LU, at which to start a refresh operation, and the second register 214-2 can indicate how many LBAs, within the LU, on which to perform the refresh operation.

The example of FIG. 2B can be used with a second approach for performing a refresh operation. The second approach can include a host (e.g., host system 120 in FIG. 1) sending a command to store a first LBA in the first register 214-1. The second approach can further include the host sending a command to store a range of LBAs in the second register 214-1. The second approach can further include the host sending a command to store a logical unit (LU) identification (ID) in the third register 214-3. In some examples, a single command can indicate to store one, two, or all three portions of data (e.g., the first LBA, the range of LBAs, and/or the LU ID) in the first register 214-1, the second register 214-2, and/or the third register 214-3, respectively. In some examples, separate commands can be used to store data in the first register 214-1, the second register 214-2, and/or the third register 214-3. Subsequent to sending the commands to store refresh data in the registers, 214-1, 214-2, 214-3, the host can send a refresh command to the memory device 230-1 to perform the refresh operation.

In response to receiving the refresh command to perform the refresh operation from the host, the memory device 230-2 can access the second register 214-2 to determine whether the second register 214-2 stores a non-zero value. In response to the second register 214-2 storing a non-zero value, the memory device 230-2 can access the first register 214-1 to determine the first LBA, access the second register 214-2 to determine the range of LBAs to perform the refresh operation on, and access the third register 214-3 to determine which LU to access to perform the refresh operation. In response to the second register 214-2 storing a value of zero (“0”), the memory device 230-1 can either return an error message or perform other refresh operations based on other stored refresh data, such as ECC counts, cell distribution, product status, etc.

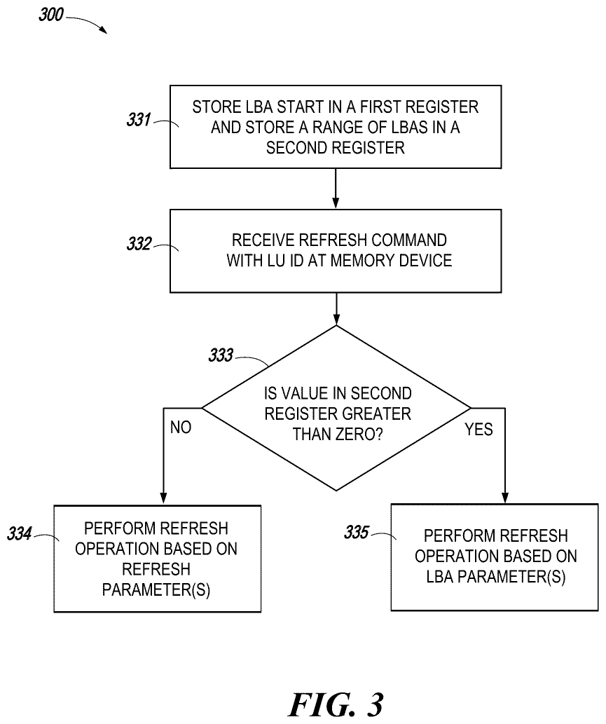

FIG. 3 is an example of a flow diagram 300 corresponding to a method for refreshing at least one LBA in accordance with some embodiments of the present disclosure. The method of flow diagram 300 can be performed using the memory device 230-1 illustrated in FIG. 2A. At block 331, the method can include storing an LBA start location in a first register (e.g., first register 214-1 in FIG. 2A) and a range of LBAs in a second register (e.g., second register 214-2 in FIG. 2A). At block 332, the method can include receiving a refresh command including a logical unit (LU) ID at a memory device (e.g., memory device 230-1 in FIG. 2A). A host can send the refresh command to the memory device.

At block 333, the method can include performing a determination of whether a value stored in the second register is greater than zero. In response to the value stored in the second register being equal to zero (e.g., “NO”), at block 334, the method can include performing a refresh operation on the first LBA and on the range of LBAs subsequent to the first LBA based on refresh parameters. The refresh parameters can include an ECC count, a cell distribution, a product status, etc. In response to the value stored in the second register being greater than zero (e.g., “YES”), at block 335, the method can include performing a refresh operation based on LBA parameter(s). The refresh operation can include refreshing data based on the LBA parameter(s). The LBA parameter(s) can include the LBA start location and the range of LBAs. Refreshing the data can include refreshing data stored at the LBA start location and through the range of LBAs.

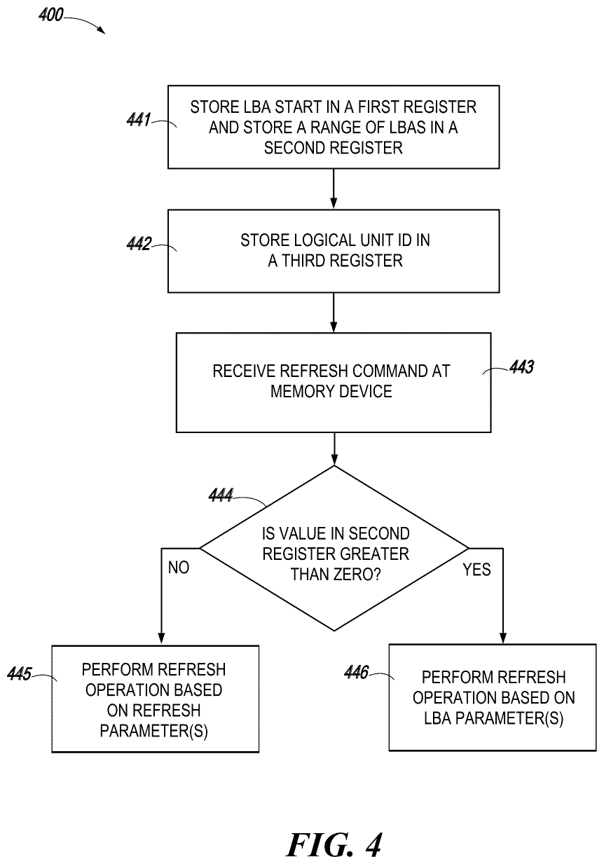

FIG. 4 is an example of a flow diagram 400 corresponding to a method for refreshing at least one LBA in accordance with some embodiments of the present disclosure. The method of flow diagram 300 can be performed using the memory device 230-2 illustrated in FIG. 2B. At block 441, the method can include storing an LBA start location in a first register (e.g., first register 214-1 in FIG. 2B) and a range of LBAs in a second register (e.g., second register 214-2 in FIG. 2B). At block 442, the method can include storing a logical unit (LU) identification (ID) in a third register (e.g., third register 114-3 in FIG. 2B). At block 443, the method can include receiving a refresh command at a memory device (e.g., memory device 230-1 in FIG. 2A). A host can send the refresh command to the memory device.

At block 444, the method can include performing a determination of whether a value stored in the second register is greater than zero. In response to the value stored in the second register being equal to zero (e.g., “NO”), at block 445, the method can include performing a refresh operation based on refresh parameters. The refresh operation can be performed on data in the first LBA and in the range of LBAs subsequent to the first LBA associated with the LU ID. The refresh parameters can include an ECC count, a cell distribution, a product status, etc. In response to the value stored in the second register being greater than zero (e.g., “YES”), at block 446, the method can include performing a refresh operation based on LBA parameter(s). The refresh operation can be performed on data stored at the LBA start location through the range of LBAs of the LU. The LBA parameter(s) can include the LBA start location and the range of LBAs of the LU.

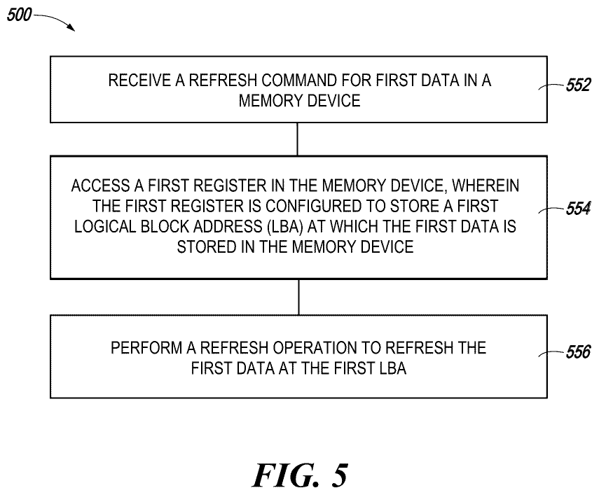

FIG. 5 is an example of a method 500 for performing a refresh operation in accordance with a number of embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, method 500 is performed by the controller 115 in coordination with the refresh manager 113 in FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 552, the method 500 can include receiving a refresh command for first data in a memory device. The refresh command can indicate to perform a refresh operation on a particular number of LBAs. The refresh command can be received by the memory device from a host.

At block 554, the method 500 can include accessing a first register in the memory device. In some examples, the host can send a command to the memory device indicating to store a first logical block address (LBA) associated with a portion of memory cells in a first of at least two registers of the array. The first register can include one or more cells of an array of memory cells of the memory device. The first register can be configured to store a first logical block address (LBA) at which the first data is stored in the memory device.

The method 500 can further include accessing a second register in the memory device, wherein the second register is configured to store a range of LBAs. In some examples, the host can determine a second portion of memory cells of the memory device to be refreshed and send a second command to store a range of LBAs associated with the second portion of memory cells in a second of the at least two registers of the array. The memory device can be configured to store the first LBA in the first register in response to receiving an instruction from a host to store the first LBA in the first register. The memory device can be configured to store the range of LBAs in the second register in response to receiving an instruction from a host to store the range of LBAs in the second register.

At block 556, the method 500 can include performing a refresh operation to refresh the first data at the first LBA. In some examples, performing the refresh operation can include refreshing the first data stored in a first portion of memory cells at the first LBA and second data stored in a second portion of memory cells at LBAs subsequent to the first LBA within the range of LBAs. The refresh operation can be performed independent of using refresh data associated with the first LBA or the range of LBAs. For example, independent of ECC counts, cell distribution data, product status, etc.

In some examples, the method can include storing a logical unit (LU) ID in a third register of the memory device. The LU ID can be where the first LBA and the range of LBAs are located. In some examples, the LU ID is stored within an argument of the initial refresh command sent by the host to the memory device. In some examples, the host can determine the first portion of memory cells and the second portion of memory cells together as a total portion of memory cells. The command sent by the host can indicate to store the first LBA as a starting LBA of the total portion in the register and the range of LBAs of the total portion in the second register. In response to receiving the command with the starting LBA and the range of LBAs, the memory device can be configured to access the first register and the second register and perform a refresh operation on a group of LBAs beginning at the starting LBA and continuing through the range of LBAs.

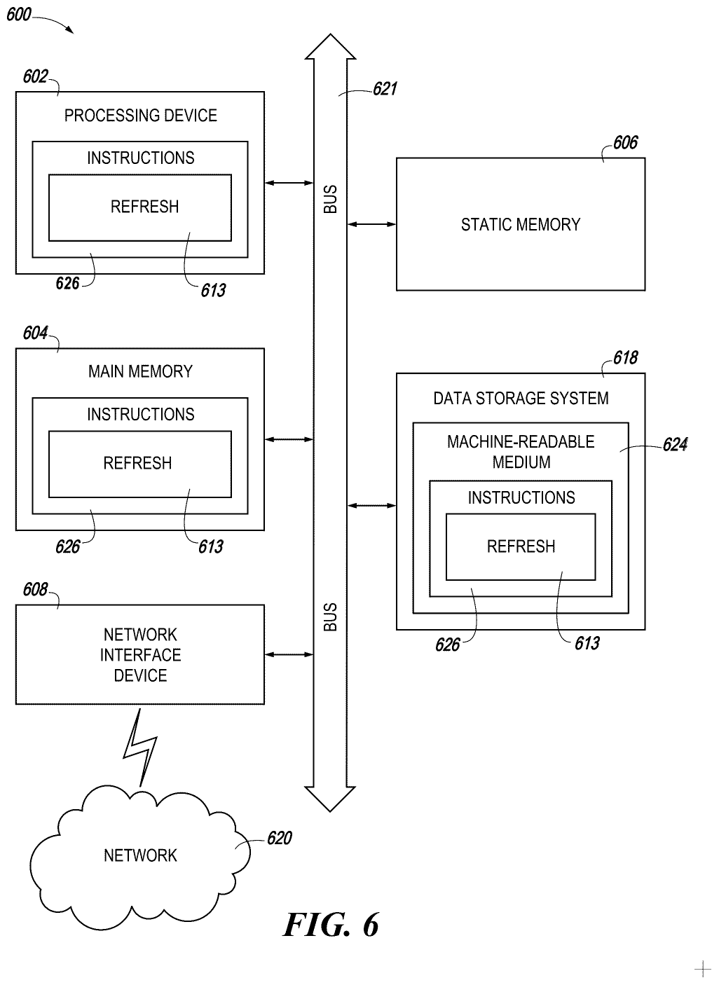

FIG. 6 is a block diagram of an example computer system 600 in which embodiments of the present disclosure may operate. For example, FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory system (e.g., the memory system 110 of FIG. 1) or can be used to perform the operations of a controller (e.g., to execute an operating system to perform operations corresponding to the refresh manager 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 621.

The processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory system 110 of FIG. 1.

In one embodiment, the instructions 626 include instructions to implement functionality corresponding to a refresh manager (e.g., the refresh manager 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
receiving a refresh command for first data in a memory device;
accessing a first register in the memory device, wherein the first register is configured to store a first logical block address (LBA) at which the first data is stored in the memory device; and
performing a refresh operation to refresh the first data at the first LBA.

2. The method of claim 1, comprising accessing a second register in the memory device, wherein the second register is configured to store a range of LBAs.

3. The method of claim 2, wherein performing the refresh operation comprises refreshing the first data stored in a first portion of memory cells at the first LBA and second data stored in a second portion of memory cells at LBAs subsequent to the first LBA within the range of LBAs.

4. The method of claim 2, wherein the memory device is configured to store the range of LBAs in the second register in response to receiving an instruction from a host to store the range of LBAs in the second register.

5. The method of claim 1, wherein the first register comprises one or more cells of an array of memory cells of the memory device.

6. The method of claim 1, comprising storing the first LBA in the register.

7. The method of claim 6, wherein the memory device is configured to store the first LBA in the first register in response to receiving an instruction from a host to store the first LBA in the first register.

8. The method of claim 1, wherein the refresh command is received from a host.

9. An apparatus, comprising:
a memory device comprising an array of memory cells, the array of memory cells comprising at least two registers, wherein:
a first of the at least two registers is configured to store a first LBA; and
a second of the at least two registers is configured to store information about a range of LBAs; and
a processing device coupled to the memory device and configured to:
receive a refresh command from a host indicating to perform a refresh operation;
access the first register in the memory device to locate the first LBA;
access the second register in the memory device to locate the range of LBAs; and
initiate the refresh operation.

10. The apparatus of claim 9, wherein the processing device is configured to perform the refresh operation on the first LBA and the range of LBAs subsequent to the first LBA.

11. The apparatus of claim 9, wherein the processing device is configured to perform the refresh operation independent of refresh data associated with the first LBA or the range of LBAs.

12. The apparatus of claim 9, wherein:
the array of memory cells comprises a third register; and
the processing device is configured to store, in the third register, a logical unit (LU) ID associated with the first LBA.

13. The apparatus of claim 12, wherein the processing device is configured to access the LU ID in the third register and perform the refresh operation in an LU associated with the LU ID.

14. The apparatus of claim 9, wherein the command comprises a logical unit (LU) ID within which to perform the refresh operation.

15. A system, comprising:
a host;
a memory system comprising:
a memory device comprising an array and in communication with the host, the array comprising at least two registers; and
a processing device coupled to the memory device;
wherein:
the host is configured to:
determine a first portion of memory cells of the memory device to be refreshed; and
send a command to store a first logical block address (LBA) associated with the portion of memory cells in a first of the at least two registers of the array; and
the processing device is configured to:
receive the command from the host; and
store the first LBA in the register.

16. The system of claim 15, wherein the host is configured to send a refresh command to the memory device indicating to perform a refresh operation.

17. The system of claim 16, wherein the memory device is configured to, in response to receiving the refresh command:
access the first register to obtain the first LBA; and
refresh the first portion of memory cells in the array associated with the first LBA.

18. The system of claim 15, wherein the host is configured to:
determine a second portion of memory cells of the memory device to be refreshed; and
send a second command to store a range of LBAs associated with the second portion of memory cells in a second of the at least two registers of the array.

19. The system of claim 18, wherein the host is configured to:
determine the first portion of memory cells and the second portion of memory cells together as a total portion of memory cells; and
the command indicates to store the first LBA as a starting LBA of the total portion in the register and the range of LBAs of the total portion in the second register.

20. The system of claim 19, wherein the memory device is configured to, in response to receiving the command with the starting LBA and the range of LBAs:
accessing the first register and the second register; and
performing a refresh operation on a group of LBAs beginning at the starting LBA and continuing through the range of LBAs.
